(19) United States
(12) Patent Application Publication
(10) Pub. No.: US 2004/0163952 A1
(43) Pub. Date: Aug. 26, 2004

(54) Magnetron with adjustable target positioning

(76) Inventors: Yury Oshmyansky, Camarillo, CA (US); Sergey Mishin, Goleta, CA (US); Richard C. Ruby, Menlo Park, CA (US); John D. Larson III, Palo Alto, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/371,862

(22) Filed: Feb. 21, 2003

(51) Int. Cl. C23C 14/34

(52) U.S. Cl. 204/298.18; 204/298.17; 204/298.19

(57) ABSTRACT

A magnetron with mechanisms for controlling the magnetic field that acts on its targets in such a manner as to provide control over erosion patterns and independent control of stress, uniformity, deposition rate, and coupling coefficient of a deposited film. A magnetron according to the present teachings includes a set of targets each for eroding a material for deposition onto a wafer contained in the magnetron and a mechanism for adjusting a racetrack position on each target. The racetrack position defines the areas of the targets from which a predominant amount of the material is eroded. The control of racetrack position enables precise control of erosion characteristics and control over stress, uniformity, deposition rate, and coupling coefficient.

### BACKGROUND OF THE INVENTION

1. Field of Invention

The present invention pertains to the field of magnetrons. More particularly, this invention relates a magnetron having controllable magnetic fields.

2. Art Background

A magnetron is a device that is commonly used for depositing a film onto a surface. The process of depositing a film onto a surface using a magnetron is commonly referred to as sputtering. For example, a magnetron may be used to sputter an aluminum-nitride film onto a silicon wafer. An aluminum-nitride film on a silicon wafer may be a step in the manufacture of piezoelectric acoustic resonator filters including film bulk acoustic resonator (FBAR) filters.

A typical magnetron includes a chamber and one or more targets that are bombarded with ions. The ion bombardment of the targets usually causes erosion of the target material. Typically, eroded material from the targets is deposited as a film onto a wafer contained in the chamber. The target material is usually selected to yield a particular substance to be deposited on the wafer. To deposit an aluminum-nitride film onto a silicon wafer, for example, the target material is typically aluminum.

It may be desirable in many applications that the film deposited onto a wafer have relatively uniform thickness over the surface of the wafer. In the manufacture of FBAR filters, for example, the greater the uniformity in the aluminum-nitride film thickness the higher the yield of the resulting filters. A higher coupling coefficient usually yields a more efficient energy transfer between the electrical and acoustic domains of the filter resulting in better quality filters. In addition, it may be desirable in many applications, e.g. FBAR filter manufacture, to control the stress characteristics of a deposited film and control the deposition rate. Unfortunately, prior magnetrons usually do not provide independent control over the stress, uniformity, deposition rate, and coupling coefficient of a deposited film.

### SUMMARY OF THE INVENTION

A magnetron is disclosed with mechanisms for controlling the magnetic field that acts on its targets in such a manner as to provide control over erosion patterns and independent control of stress, uniformity, deposition rate, and coupling coefficient of a deposited film. A magnetron according to the present teachings is particularly advantageous for sputtering highly piezoelectric aluminum nitride for FBAR filters and meeting all of the stringent requirements of that technology.

A magnetron according to the present teachings includes a set of targets each for eroding a material for deposition onto a wafer contained in the magnetron and a mechanism for adjusting a racetrack position on each target. The racetrack position defines the areas of the targets from which a predominant amount of the material is eroded. The control of racetrack positions enables precise control of erosion characteristics and control over stress, uniformity, deposition rate, and coupling coefficient. A magnetron according to the present teachings may also include a mechanism for adjusting a distance of each target from the wafer to provide additional control over the uniformity of film thickness.

Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIGS. 1a-1b illustrate a magnetron according to the present teachings;

FIGS. 2a-2g illustrate control of the position of a racetrack on a target in response to changes in the arrangement of magnets and pole pieces in a magnetic structure;

FIGS. 3a-3c illustrate the dependence of coupling coefficient, deposition rate, and film stress on the strength of the magnetic field.

FIGS. 4a-4b illustrate the film deposition characteristics of a pair of targets in a magnetron;

FIG. 5 illustrates changes in the film deposition characteristics of a target in response to changes in a distance of the target from a wafer;

FIGS. 6a-6c illustrate the changes in uniformity of film thickness in response to changes in distance between the targets in a magnetron.

### DETAILED DESCRIPTION

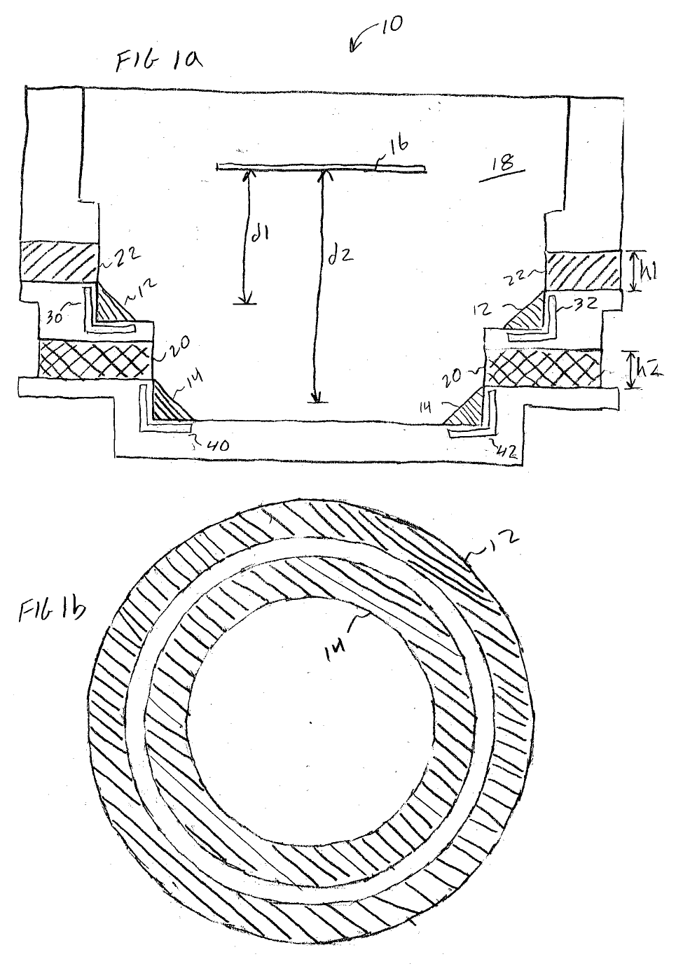

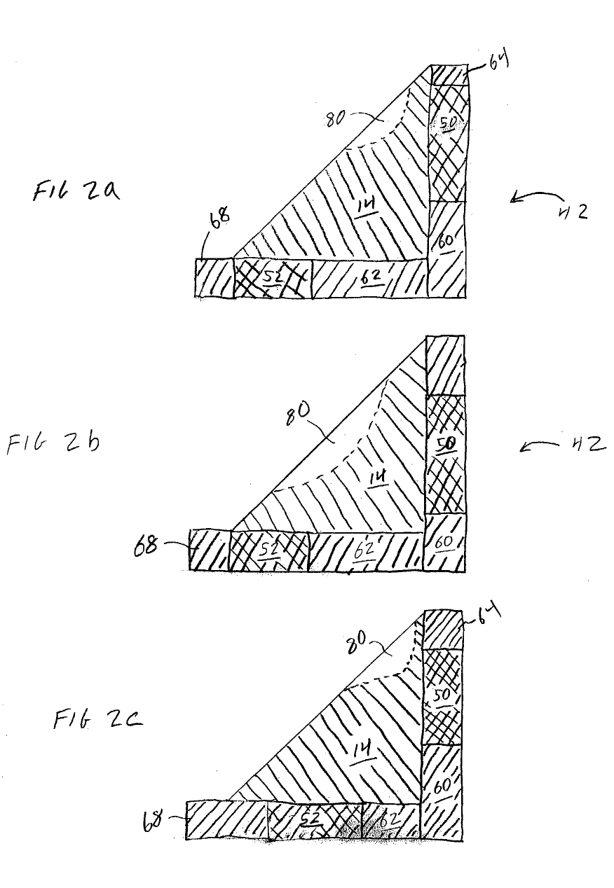

FIG. 1a shows a cross sectional side view of a magnetron 10 according to the present teachings. The magnetron 10 includes a pair of targets 12-14 having a conical shape. FIG. 1b shows a top view of the targets 12-14. The target 12 may be referred to as the upper target and the target 14 may be referred to as the lower target. The magnetron 10 includes a set of magnetic structures 30-32, 40-42 for generating magnetic fields that act on the targets 12-14. The magnetic structures 30-32, 40-42 are located behind the horizontal and vertical edges of the targets 12-14. In one embodiment, the magnetic structures 30-32, 40-42 are contained in a copper assembly of radial pockets (from a top view of the magnetron 10) for holding magnets and pole pieces.

The overall structure of the magnetron 10 forms a chamber 18 that encloses a wafer 16. The chamber 18 contains a gas and electrical potentials are applied to the targets 12-14 during a sputtering operation. The interaction of electrons and the gas contained in the chamber 18 creates ions that under influence of the electrical potentials applied to the targets 12-14 accelerate toward and hit the targets 12-14, thereby causing erosion of material from the targets 12-14 and the deposition of eroded material onto the wafer 16.

The chemical make up of the gas in the chamber 18 together with the material from which the targets 12-14 are made are pre-selected for deposition of a desired substance onto the wafer 16. In one embodiment, magnetron 10 is used for sputtering thin films of highly piezoelectric aluminum nitride. The chamber 18 contains nitrogen and argon gas and the targets 12-14 are made of aluminum. The wafer 16 may be a silicon wafer.

In one embodiment, the electrical potentials applied to the targets 12-14 are reversed in polarity at a frequency of 40 Kilohertz. The periodic reversal of the electrical potentials causes ions to alternate between striking the targets 12-14 so that erosion occurs from both targets 12-14.

The targets 12-14 are conical each having a center axis oriented collinear with a center axis of the opposing wafer 16. Each target 12-14 has an independent magnetic field. The strength and position of the magnetic field of each target 12-14 is adjustable and enables control over the stress in the film deposited on the wafer 16 and control over the uniformity of deposition while maintaining a high deposition rate and a highly piezoelectric film structure.

In order to control these parameters, the position on the targets 12-14 from which the predominant amount of material is eroded is controllable in the magnetron 10. The area of the targets 12-14 from which the predominant amount of material is eroded is hereinafter referred to as the “racetrack.” If the racetrack on the lower target 14 is moved down and to the center of the lower target 14 then a higher film thickness is deposited on the center of wafer 16. If the racetrack on the upper target 12 is moved down and to the center of the upper target 12 then a higher film thickness is deposited on the edge of wafer 16.

The control of racetrack position enables fine control of the stress and uniformity in the film deposited on the wafer 16. The magnetron 10 enables a user to control film stress from a highly tensile to highly compressive state. The magnetron 10 is designed in such manner that it can be easily altered to meet the different stress requirements of different products. If compressive stress is desired, the magnetic field is increased and the racetrack on the upper target 12 is moved towards the top while the racetrack on the lower target 14 is moved down. If tensile stress is desired, the magnetic field is decreased and the racetrack on the upper target 12 is moved towards the bottom while the racetrack on the lower target 14 is moved up toward the top. After the desired stress is achieved, the distance between the targets 12-14 may be set to optimize uniformity.

Unlike prior magnetrons, the magnetron 10 is designed for adjusting the distance between the targets 12-14 because it does not have any ground or anodes between the targets 12-14. Nor does the magnetron 10 have a shared center pole piece as do some prior art magnetrons. In addition, the magnetron has two separate copper plates that have completely separate magnetic fields and cooling lines (not shown).

The distance between the wafer 16 and the targets 12-14 may be optimized for best uniformity. The sputtering gas pressure may be used to adjust stress. An increase in pressure leads to a higher deposition rate in the center of the wafer 16. To counteract this decrease in film thickness uniformity, a DC power supply may be used to apply a bias to the targets 12-14 since DC bias has almost no impact on stress.

In one embodiment, the magnetic structures 30-32 for the upper target 12 include between 12 and 60 horizontal magnets and between 20 and 60 vertical magnets and between 20 and 180 individual pole pieces and two common pole pieces. The size and the strength of the magnets and the shape of pole pieces in the magnetic structures 30-32 may be varied to move the “racetrack” of the upper target 12 from the top to the bottom of the upper target 12. Control of racetrack position on the upper target 12 may be used to control of the angle, energy, and amount of material arriving at different parts of the wafer 16 from the upper target 12.

In addition, the deposition rate and piezoelectric properties of the film deposited onto the wafer 16 from the upper target 12 may be controlled by adjusting the strength of the magnetic field generated by the magnetic structures 30-32. A low magnetic field strength from the magnetic structures 30-32 yields a higher deposition rate. A magnetic field strength that acts on the upper target 12 that is too low or too high reduces the coupling coefficient of the film deposited on the wafer 16. Coupling coefficient is a measure of piezoelectricity of the film, i.e. the efficiency of converting acoustic energy to electrical and vice versa. An optimum magnetic field strength may be used for both the deposition rage and the coupling coefficient.

In one embodiment, the magnetic structures 40-42 of the lower target 14 include between 14 and 42 horizontal magnets and between 14 and 42 vertical magnets. The magnetic structures 40-42 also includes between 14 and 126 individual pole pieces and two common pole pieces. The size and the strength of the magnets and the shape of pole pieces in the magnetic structures 40-42 may be selected and adjusted to move the racetrack of the lower target 14 from the top to the bottom of the lower target 14. Control of racetrack position on the lower target 14 enables control of the angle, energy, and amount of material arriving at different parts of the wafer 16 from the lower target 14. This in turn enables control of stress and uniformity in the film formed on the wafer 16. Adjustments to the strength of the magnetic field from the magnetic structures 40-42 may also be used to control the deposition rate and piezoelectric properties of the film deposited on the wafer 16. A lower strength magnetic field acting on the lower target 14 yields a higher deposition rate from the lower target 14. A magnetic field strength that is too high or too low reduces the coupling coefficient of the deposited film.

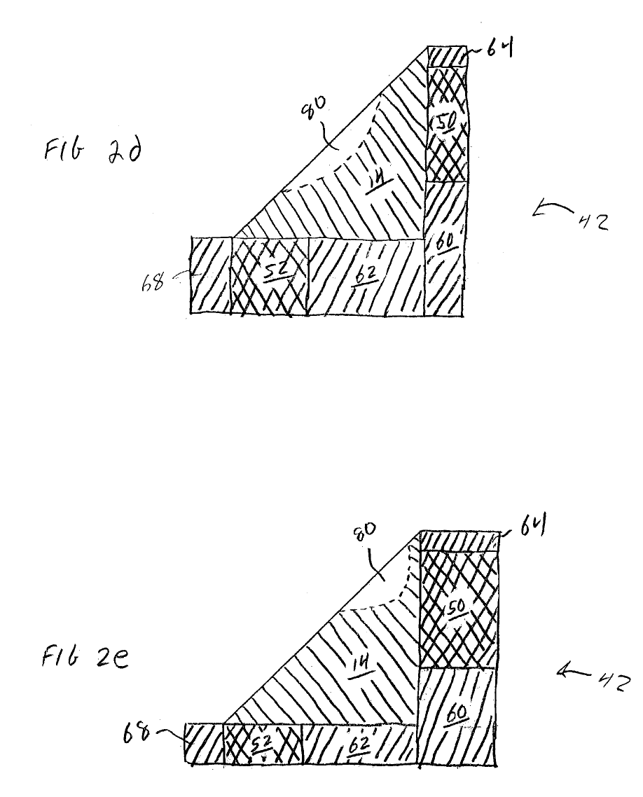

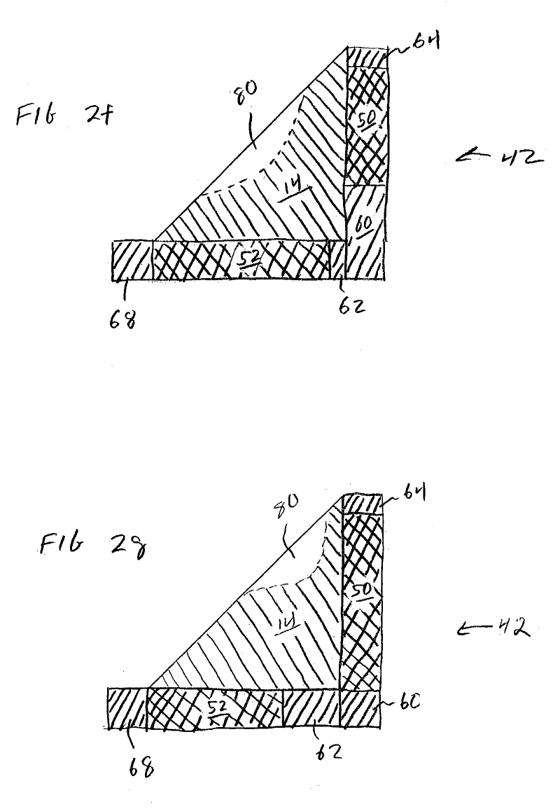

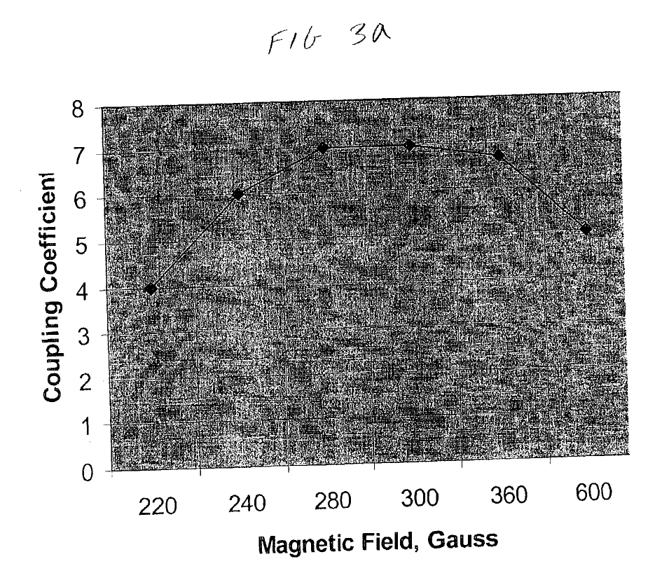

FIGS. 2a-2g illustrate control of the position of a racetrack 80 on the lower target 14 using changes in the arrangement of magnets and pole pieces in the magnetic structure 42. The magnetic structure 42 in one embodiment includes a vertical magnet 50, a horizontal magnet 52, and a set of pole pieces 60-68. The pole pieces 60-68 may be made of a non-magnetic material—for example aluminum. The proper selection of size, strength, and position of the magnets 50-52 and the positions and shapes of the pole pieces 60-68 may be used to move the racetrack 80 from the top to the bottom of the lower target 14 by changing the strength and positions of the magnetic fields that act on the lower target 14.

FIG. 2a shows an arrangement of the magnets 50-52 and pole pieces 60-68 that position the racetrack 80 on the lower target 14 in a manner that yields the maximum target erosion in a direction that is substantially perpendicular from the surface at the lower target 14. This positioning of the racetrack 80 yields the maximum material erosion rate from the lower target 14.

FIG. 2b shows an arrangement of the magnets 50-52 and pole pieces 60-68 that cause the racetrack 80 to move down and to the center of the lower target 14. This arrangement of the magnets 50-52 and pole pieces 60-68 is such that the vertical magnet 50 is moved down which causes the position of the racetrack 80 to move down and to the center.

FIG. 2c shows an arrangement of the magnets 50-52 and pole pieces 60-68 that cause the racetrack 80 to move up the lower target 14. This arrangement of the magnets 50-52 and pole pieces 60-68 is such that the horizontal magnet 52 is moved to the right away from the center of the magnetron 10.

FIG. 2d shows another arrangement of the magnets 50-52 and pole pieces 60-68 that cause the racetrack 80 to move down and to the center of the lower target 14. This arrangement of the magnets 50-52 and pole pieces 60-68 increases the magnetic field from the horizontal magnet 52. This may be accomplished by increasing the thickness of the horizontal magnet 52 and the corresponding pole pieces 62 and 68 or by stacking horizontal magnets and pole pieces. Alternatively, the racetrack 80 may be moved down and to the center of the lower target 14 by decreasing the thickness of the vertical magnet 50 relative to the thickness of the horizontal magnet 52.

FIG. 2e shows another arrangement of the magnets 50-52 and pole pieces 60-68 that cause the racetrack 80 to move up the lower target 14. This arrangement of the magnets 50-52 and pole pieces 60-68 increases the magnetic field from the vertical magnet 50. This may be accomplished by increasing the thickness of the vertical magnet 50 and the corresponding pole pieces 60 and 64 or by stacking vertical magnets and pole pieces. Alternatively, the racetrack 80 may be moved up the lower target 14 by decreasing the thickness of the horizontal magnet 52 relative to the thickness of the vertical magnet 50.

FIG. 2f shows yet another arrangement of the magnets 50-52 and pole pieces 60-68 that cause the racetrack 80 to move down and to the center of the lower target 14. This arrangement of the magnets 50-52 and pole pieces 60-68 increases the length of the horizontal magnet 52 relative to that shown in FIG. 2a. This also increases the strength of the magnetic field from the horizontal magnet 52 that acts on the lower target 14.

FIG. 2g shows yet another arrangement of the magnets 50-52 and pole pieces 60-68 that cause the racetrack 80 to move up the lower target 14. This arrangement of the magnets 50-52 and pole pieces 60-68 increases the length of the vertical magnet 50 relative to that shown in FIG. 2a. This also increases the strength of the magnetic field from the vertical magnet 50 that acts on the lower target 14.

In other alternative arrangements, the position of the racetrack 80 on the lower target 14 may be adjusted by using magnets having variable residual induction. In such embodiments, the racetrack 80 moves to the side of the magnets with the higher residual inductions.

In yet another alternative, the position of the racetrack 80 on the lower target 14 may be adjusted by adjusting the widths of the magnets. In such embodiments, the racetrack 80 moves to the side of the wider magnet.

Similar adjustments to the magnets and pole pieces in the magnetic structures 30-32 may be used to adjust the racetrack position of the upper target 12.

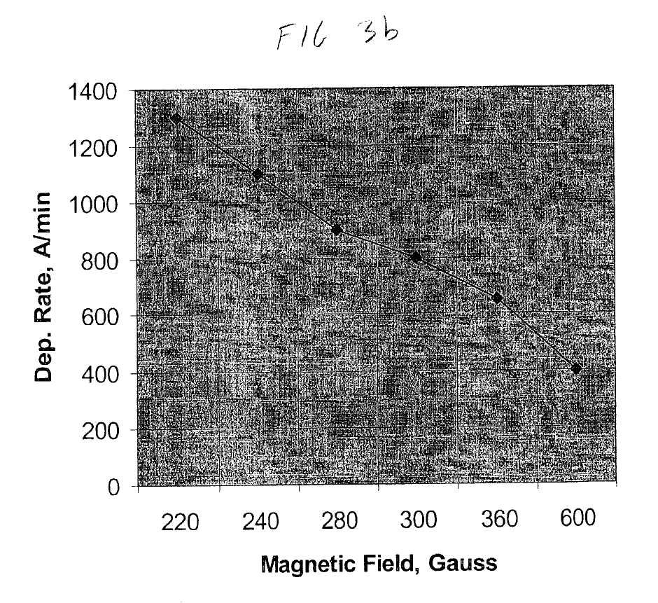

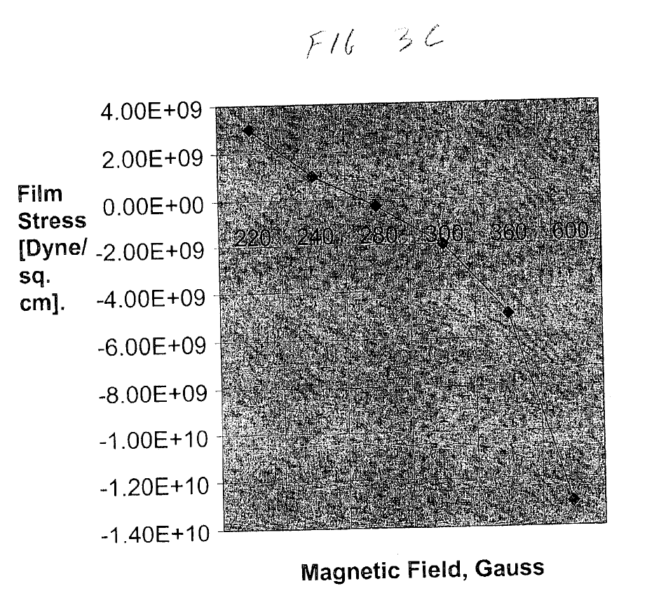

FIG. 3a illustrates the dependence of electroacoustic coupling coefficient of aluminum-nitride on the strength of the magnetic field. FIG. 3b illustrates the dependence of the deposition rate on the strength of the magnetic fields. FIG. 3c illustrates the dependence of film stress on the position of the racetrack for a magnetron with two targets as a function of the strength of the magnetic field.

The present techniques for adjusting magnetic field strength/racetrack position enables a controllable change of film properties for material coming off that target. The adjustments to racetrack position may be combined with adjustments to the distance between the upper and lower targets 12-14 to achieve a desired uniformity and desired film stress level on the wafer 16.

The plane of the upper target 12 is positioned a distance d1 from the plane of the wafer 16 and the plane of the lower target 14 is positioned a distance d2 from the plane of the wafer 16. The distance d2-d1 between the targets 12-14 may be adjusted by adjusting a height h2 of a spacer 20. In addition, the distances d1 and d2 may be adjusted together by adjusting a height h1 of a spacer 22. The spacer 20 provides a mechanism for adjusting the distance d2-d1 between the targets 12-14 that may be use to balance the film deposition characteristics of the targets 12-14 and thereby enhance uniformity in the thickness of the film formed on the wafer 16. The spacer 22 provides a mechanism for adjusting the distances d1 and d2 together.

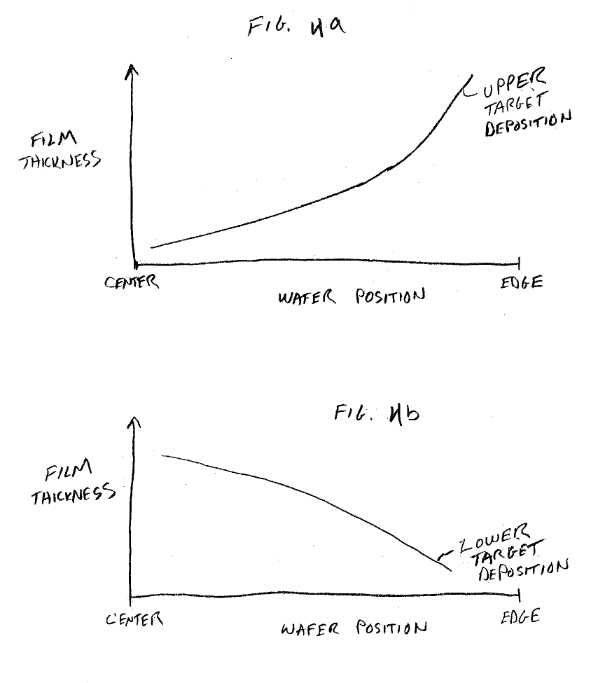

FIGS. 4a-4b are graphs that illustrate the film deposition characteristics of the upper target 12 and the lower target 14, respectively. The graphs shown represent the thickness of material deposited onto the wafer 16 from the corresponding target as a function of wafer position from the center of the wafer 16 to the extreme outer edge of the wafer 16 for a given arrangement of the magnets and pole pieces in the magnetic structures 30-32 and 40-42.

FIG. 4a shows that a greater portion of the material eroded from the upper target 12 accumulates onto areas of the wafer 16 near the edge of the wafer 16. This is a characteristic of the angles of erosion from the upper target 12 and the radial position of the upper target 12 in relation to the wafer 16.

In contrast, FIG. 4b shows that a greater portion of the material deposited on the wafer 16 from erosion from the lower target 14 accumulates near the center of the wafer 16. This is a characteristic of the angles of erosion from the lower target 14 and the radial position of the lower target 14 in relation to the wafer 16.

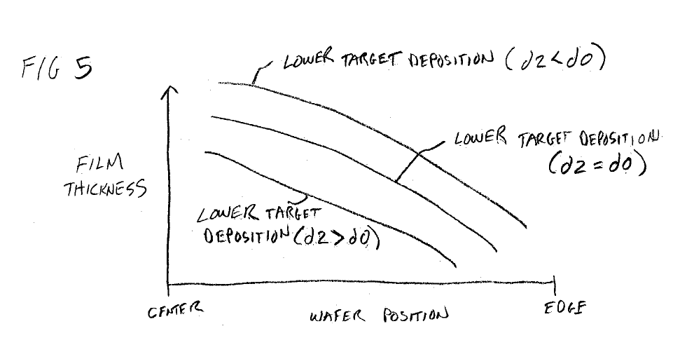

FIG. 5 illustrate changes in the film deposition characteristics of the lower target 14 in response to changes in the distance d2 of the lower target 14 from the wafer 16 for a given arrangement of the magnets and pole pieces in the magnetic structures 30-32 and 40-42. For a given distance d2=d0, material deposited on the wafer 16 from erosion from the lower target 14 has a characteristic profile with more material deposited near the center of the wafer 16 and less material deposited near the edge of the wafer 16. If the distance d2 is reduced to a distance d2<d0, material deposited on the wafer 16 from erosion from the lower target 14 has a similar characteristic profile but with greater magnitude than if d2=d0. If the distance d2 is increase to a distance d2>d0, then material deposited on the wafer 16 from erosion from the lower target 14 has a similar characteristic profile but with less magnitude than if d2=d0.

The film deposition characteristics of the upper target 12 exhibits similar changes in response to changes in the distance d1 of the upper target 12 from the wafer 16.

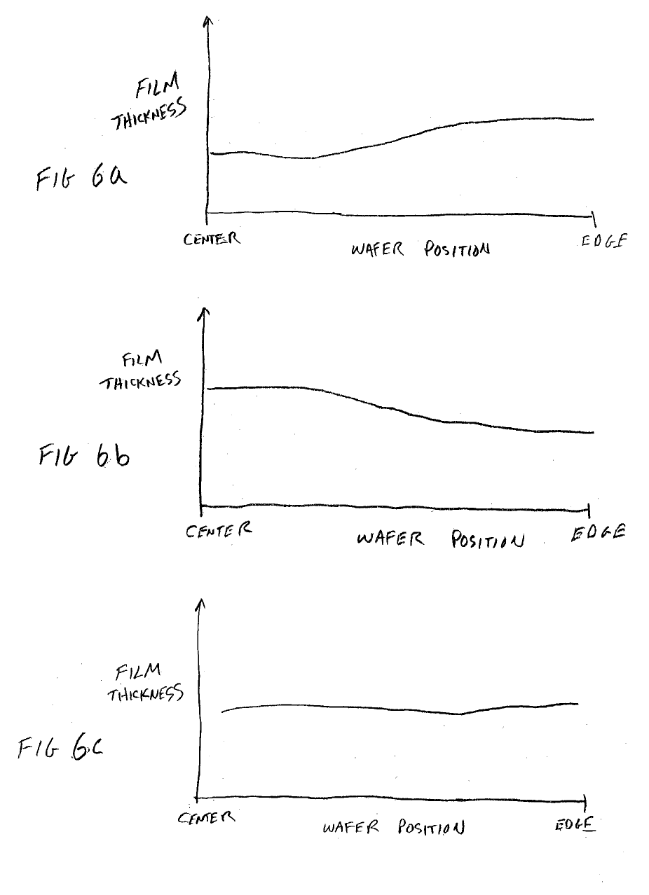

FIGS. 6a-6c illustrate the changes in uniformity of film thickness in response to changes in the height h1 of the spacer 20 for a given height h2 of the spacer 22. The graphs shown represent the overall thickness of material deposited onto the wafer 16 from both the upper and lower targets 12-14 as a function of wafer position from the center of the wafer 16 to the extreme outer edge of the wafer 16 for a given arrangement of the magnets and pole pieces in the magnetic structures 30-32 and 40-42.

FIG. 6a shows a film thickness profile that includes a thinner film near the center of the wafer 16 and a thicker film near the edge of the wafer 16. This film thickness profile corresponds to a height h1 of the spacer 20 that positions the lower target 14 too far away from the wafer 16 relative to the distance of the upper target 12 from the wafer 16, i.e. the relative distance d2-d1 is too high.

FIG. 6b shows a film thickness profile that includes a thicker film near the center of the wafer 16 and a thinner film near the edge of the wafer 16. This film thickness profile corresponds to a height h1 of the spacer 20 that positions the lower target 14 too close to the wafer 16 relative to the distance of the upper target 12 from the wafer 16, i.e. the relative distance d2-d1 is too low.

FIG. 6c shows a film thickness profile that includes a relatively uniform thickness of material across the wafer 16. This film thickness profile corresponds to a height h1 of the spacer 20 that positions the lower target 14 relative to the upper target 12 for optimal uniformity of film thickness on the wafer 16, i.e. the relative distance d2-d1 balances the film deposition characteristics of the upper target 12 with the film deposition characteristics of the lower target 14.

An operator of the magnetron 10 may determine a set of profiles that indicate the film deposition characteristics of the targets 12-14 as a function of target distance from the wafer 16 and magnetic field strength and positioning of magnetic structures 30-32 and 40-42. Each profile indicates film thickness as a function of wafer position for a given distance between the wafer 16 and the corresponding target and given arrangement of the magnetic structures 30-32 and 40-42. These profiles may be determined by experimentation using actual sputtering operations for a number of pre-selected positionings of the targets 12-14 relative to the wafer 16 and arrangements of the magnetic structures 30-32 and 40-42. An optimal positioning of the targets 12-14 and arrangements of the magnetic structures 30-32 and 40-42 may then be selected in response to the profiles. The optimal positioning provides the distances d1 and d2 of the targets 12-14 from the wafer 16 that balance the deposition profiles and yield substantial uniformity in film thickness over the surface of the wafer 16. The heights of the spacer 20 and possibly the spacer 22 may then be adjusted in accordance with the optimal positioning of the targets 12-14.

In one embodiment, the magnets in the magnetic structures 30-32, 40-42 are maintained at the potential of the targets 12-14 to provide the greatest interaction between magnetic and electrical fields. This produces the strongest magnetic field on the target surface in order to cause a uniform and self-adjusted erosion target profile. The present techniques enable adjustments to the strength of the magnetic field on the target surface by a factor of ten. The strength of the magnetic field on the target surface is constant and within +/−3% during target life as determined by the stability of the permanent magnets employed. In one embodiment, the magnetron 10 yields a high deposition rate and a thickness uniformity of better than 0.2% on a six inch wafer 16.

It is highly preferable to employ a high-density plasma in the chamber 18 during aluminum-nitride deposition. The upper and lower targets 12-14 without an anode, ground or floating potential in combination with one AC power supply (20 kHz to 200 kHz) enables a very high-density and stable plasma to be generated. Since there is no anode, ground, or grid structure on which insulating aluminum-nitride may be deposited, the plasma may be maintained in uniformity as the deposition proceeds. Prior magnetrons that employ an anode, ground or floating potential between the two targets are often hindered by plasma changes throughout the deposition cycle as these surfaces become coated with a progressively thicker dielectric (aluminum-nitride) film. These surfaces build up charge that causes plasma instability during deposition in prior magnetrons.

The magnetron 10 may use any size and shape of conical targets. A designer may optimize film uniformity, stress, target life and energy with which the wafer 16 is bombarded by adjusting the shape of each target to match the fields produced by the corresponding magnet and pole piece combination.

Aluminum-nitride deposition at about 450 degrees C. produces piezoelectric material with the highest coupling coefficient. Uniformity of temperature across the wafer 16 provides a uniform coupling coefficient across the wafer 16. The wafer 16 may be suspended by four points near its edge thereby enabling it to heat up to 450 degrees C. uniformly. This is due to the high-density and uniform plasma produced by the AC deposition.

The magnetic fields on both of the targets 12-14 may have the same or opposite direction. An unbalanced magnetron and a substantially increased plasma density may be obtained by using the same direction of the magnetic field on both the targets 12-14.

The plasma density may be varied by the changing the direction of the electric field by means of grounding the lower target 14. In this configuration, sputtering still occurs from the lower target 14.

The mechanisms in magnetron 10 for adjusting magnetic fields and distances between targets render it particularly advantageous for the manufacture of FBAR filters. An FBAR filter is a series of electrically connected, air suspended membrane type resonators of piezoelectric aluminum nitride, sandwiched between two layers of metal electrodes. For application to the microwave cellular phone application, as an example, FBAR filters are constructed on a silicon wafer as individual die about 1 by 1 millimeter square. A 150 mm diameter wafer may host over ten thousand individual filters, all of which are preferably within approximately 0.2% of the nominal center frequency. A higher electro-acoustic coupling coefficient kₜ² (measure of piezoelectricity of the material) in the aluminum nitride yields a lower insertion loss in cellular phone band filters. Coupling coefficients close to 7% are preferable to produce the best quality filters in these applications. The thickness of the aluminum nitride, in part, determines the frequency of the filter. Uniformity of the aluminum nitride film across wafer must be better than 0.2% one sigma for the filter yield to be 70%. If uniformity degrades to 1%, yield will be proportionately reduced to 14%, rendering commercial manufacturing of these filters problematic. Stress in the films should be user selectable in order to force the membrane to stay flat or bow up as desired. Given the desirability of manufacturing filter products at very low cost, magnetrons that manufacture this material should preferably produce aluminum-nitride films at about 1000 angstroms/minute deposition rate.

The foregoing detailed description of the present invention is provided for the purposes of illustration and is not intended to be exhaustive or to limit the invention to the precise embodiment disclosed. Accordingly, the scope of the present invention is defined by the appended claims.

What is claimed is:

1. A magnetron, comprising:
a set of targets each for eroding a material for deposition onto a wafer contained in the magnetron;
means for adjusting a racetrack position on each target wherein each racetrack position defines an area of the corresponding target from which a predominant amount of the material is eroded.

2. The magnetron of claim 1, wherein the means for adjusting a racetrack position includes means for applying an independent magnetic field to each target.

3. The magnetron of claim 1, wherein the means for adjusting a racetrack position includes means for adjusting a strength of a magnetic field that acts on the corresponding target.

4. The magnetron of claim 1, wherein the means for adjusting a racetrack position includes means for adjusting a position of a magnetic field that acts on the corresponding target.

5. The magnetron of claim 1, wherein the means for adjusting a racetrack position comprises an adjustable arrangement of magnets and pole pieces.

6. The magnetron of claim 5, wherein each racetrack position is adjusted by adjusting a size of each magnet and pole piece in the corresponding arrangement of magnets and pole pieces.

7. The magnetron of claim 5, wherein each racetrack position is adjusted by adjusting a position of each magnet and pole piece in the corresponding arrangement of magnets and pole pieces.

8. The magnetron of claim 5, wherein each target has a shape which is selected to match a magnetic field generated by the corresponding arrangement of magnets and pole pieces.

9. The magnetron of claim 5, wherein the magnets in each arrangement are maintained at an electrical potential of the corresponding target.

10. The magnetron of claim 1, further comprising means for adjusting a distance of each target from the wafer.

11. The magnetron of claim 10, wherein the targets form a conical structure including an upper target and a lower target.

12. The magnetron of claim 11, wherein the means for adjusting a distance of each target from the wafer comprises a spacer located between the upper target and the lower target.

13. The magnetron of claim 12, wherein erosion of the upper target yields a first profile of deposition on the wafer and erosion of the lower target yields a second profile of deposition on the wafer and the spacer has a height that is selected to balance the first and second profiles.

14. The magnetron of claim 11, wherein the means for adjusting a distance of each target from the wafer further comprises a spacer for adjusting a distance of both the upper and lower targets from the wafer.

15. A method for sputtering in a magnetron, comprising the steps of:
eroding a material from a set of targets onto a wafer contained in the magnetron;
adjusting a racetrack position on each target wherein each racetrack position defines an area of the corresponding target from which a predominant amount of the material is eroded.

16. The method of claim 15, wherein the step of adjusting a racetrack position includes the step of adjusting a strength of a magnetic field that acts on the corresponding target.

17. The method of claim 15, wherein the step of adjusting a racetrack position includes the step of adjusting a position of a magnetic field that acts on the corresponding target.

18. The method of claim 15, wherein the step of adjusting a racetrack position includes the step of applying an independent magnetic field to each target.

19. The method of claim 15, further comprising the step of adjusting a distance of each target from the wafer.
